(19) United States
(12) Patent Application Publication
(10) Pub. No.: US 2015/0179490 A1
(43) Pub. Date: Jun. 25, 2015

(54) SUBSTRATE PROCESSING APPARATUS, PROGRAM AND SUBSTRATE PROCESSING METHOD

(71) Applicant: SCREEN Holdings Co., Ltd., Kyoto (JP)

(72) Inventor: Masahiro Yamamoto, Kyoto-shi (JP)

(21) Appl. No.: 14/408,025

(22) PCT Filed: Jun. 25, 2013
(86) PCT No.: PCT/JP2013/067304

§ 371 Date: Dec. 15, 2014

(30) Foreign Application Priority Data
Jul. 13, 2012 (JP) 2012-157717
Mar. 12, 2013 (JP) 2013-048988

(51) Int. Cl. H01L 21/677; B25J 11/00; H01L 21/77

(52) U.S. Cl. CPC H01L 21/67772; H01L 21/67769; H01L 21/77; B25J 11/0095

(57) ABSTRACT

A substrate processing apparatus includes a sealed container which interiorly has a space for housing substrates and is provided with an opening for introducing or discharging the substrates, an opening/closing mechanism for opening and closing the opening, a substrate processing part for performing cleaning process on the substrates, and a first transfer robot for discharging and introducing the substrates from and into the sealed container. Further, the substrate processing apparatus includes a schedule creating part adapted to create schedule data which defines timings at which the opening/closing mechanism opens and closes the opening, and timings at which the substrate transferring part introduces the substrates in the sealed container or discharges the substrates from the sealed container, according to time periods of processing of the substrates into the substrate processing part.

### TECHNICAL FIELD

The present invention relates to techniques for successively performing processing on plural substrates with processing parts and, more particularly, relates to techniques for discharging substrates from sealed containers housing plural substrates or for introducing substrates into these sealed containers.

### BACKGROUND ART

In semiconductor fabrication processes, processing of wafers (substrates) is performed within clean rooms, in order to improve the yield and the qualities. However, permissible sizes of foreign substances such as dusts have been extremely reduced, for reasons of higher integration of semiconductor devices and fineness of circuits. Therefore, so-called mini-environment systems have been employed, in some cases.

With such a mini-environment system, highly-cleaned spaces are locally formed, rather than an entire cleaning room is highly cleaned. For example, a carrier cassette containing substrates is housed within a sealed container (for example, FOUR: Front-Opening Unified Pod), in order to transfer or store the substrates between respective processes (or within the respective processes).

There have been known interface portions called load ports for ejecting and introducing substrates within sealed containers from and into processing parts in a substrate processing apparatus (a semiconductor fabrication device) and, also, for receiving and delivering the sealed containers from and to transfer devices. Within the clean room, particularly, the insides of the sealed containers and the substrate processing apparatus are super-highly cleaned, and the substrate receiving/delivering space between the sealed containers and the semiconductor fabrication device is highly cleaned to a predetermined degree, thereby reducing the construction cost and the operating cost for the cleaning room (Patent Document 1, for example).

### PRIOR ART DOCUMENTS

### Patent Documents

Patent Document 1: Japanese Patent Application Laid-Open No. 2010-232560

### SUMMARY OF INVENTION

### Problems to be Solved by the Invention

On the other hand, in cases of ordinary substrate treatment, even if a sealed container is opened at the start of processes and is kept in this state, and the opening of the sealed container is closed after the completion of the processes, this hardly induces problems in the substrate processing, in particular. However, depending on the types of substrates, there has been a risk of damages of the substrates, such as oxidation, due to the continuation of the opened state.

In order to avoid this problem, conventional semiconductor fabrication devices have been controlled such that, after the elapse of a certain time period since taking out of a single (or a necessary number of) substrate(s) from a sealed container, the opening of the sealed container is closed, and the sealed container is kept closed until a transfer device next comes to take a substrate. However, in this case, the sealed container is continuously in the opened state until the elapse of the aforementioned certain time period and, therefore, there has been a risk of damages of substrates. In general, the opening/closing device for opening and closing the sealed container is in a control system independent of the semiconductor fabrication device. Therefore, the transfer device transmits a signal indicating that a substrate is to be discharged or a substrate is to be introduced, to the opening/closing device and, thereafter, the opening/closing device performs an operation for, opening/closing the sealed container. Therefore, when the transfer device discharges a substrate from the sealed container or introduces it into the sealed container, it is necessary that the transfer device is kept on standby until the opening of the sealed container is opened. Accordingly, due to the occurrence of the time period for which the transfer device is kept on standby, there has been a risk of reduction of the operating ratio of the semiconductor fabrication device, namely the substrate processing efficiency.

The present invention was made in view of the aforementioned problem and aims at providing techniques for suppressing the reduction of the substrate processing efficiency and for alleviating damages exerted, due to opening of sealed containers, on substrates housed therein.

### Means for Solving the Problems

In order to overcome the aforementioned problem, in a first aspect, there is provided a substrate processing apparatus for performing processing on a substrate, wherein the substrate processing apparatus includes: a sealed container provided with an opening for introducing and discharging a substrate therein and therefrom; an opening/closing part adapted to open and close the opening; a processing part adapted to perform predetermined processing on the substrate; a substrate transferring part adapted to discharge the substrate from the sealed container or to introduce the substrate into the sealed container; a schedule creating part adapted to create a schedule which defines a time period for which the opening/closing part opens and closes the opening, and a time period for which the substrate transferring part discharges the substrate from the sealed container or introduces the substrate into the sealed container, according to a substrate processing time period in the processing part; and an execution command part adapted to command the opening/closing part and the substrate transferring part to execute operations, based on the schedule.

Further, in a second aspect, in the substrate processing apparatus in the first aspect, the schedule creating part is adapted to create the schedule such that the opening/closing part closes the opening, when a time width until the substrate transferring part next starts discharging a substrate from the sealed container or starts introducing a substrate into the sealed container is longer than a time width which is a sum of a time width required for a closing operation of the opening/closing part and a time width required for an opening operation of the opening/closing part, in a state where the opening has been opened by the opening/closing part.

Further, in a third aspect, in the substrate processing apparatus in the first or second aspect, the schedule creating part is adapted to create the schedule such that the opening/closing part starts opening the opening, at an earlier timing, by equal to or more than a time width required for an opening operation of the opening/closing part, than a time at which the substrate transferring part is to next start discharging a substrate from the sealed container or to next start introducing a substrate into the sealed container, in a state where the opening has been closed by the opening/closing part.

Further, in a fourth aspect, the substrate processing apparatus in any one of the first to third aspects further includes an inert-gas supply part for supplying an inert gas to an inside of the container, and a concentration acquisition part for acquiring an inert-gas concentration within the sealed container, wherein the schedule creating part is adapted to create the schedule, such that the opening/closing part closes the opening, when the inert-gas concentration acquired by the concentration acquisition part is lower than a predetermined reference value.

Further, in a fifth aspect, in the substrate processing apparatus in any one of the first to fourth aspects, the opening/closing part includes a first opening/closing part for closing the opening, and a second opening/closing part for closing the opening, such that, when the opening is closed thereby, the sealed container is sealed to a lower degree than when the opening is closed by the first opening/closing part, and the schedule creating part is adapted to create a schedule which defines a timing of an opening/closing operation of the second opening/closing part.

Further, in a sixth aspect, there is provided a program which can be read by a computer, wherein the program is adapted to be executed by the computer, thereby causing the computer to function as a schedule creating part in a substrate processing apparatus including a sealed container provided with an opening for introducing and discharging a substrate therein and therefrom, an opening/closing part adapted to open and close the opening, a processing part adapted to perform predetermined processing on the substrate, and a substrate transferring part adapted to discharge the substrate from the sealed container or to introduce the substrate into the sealed container, wherein the schedule creating part is adapted to create a schedule which defines a timing at which the opening/closing part opens and closes the opening, and a time period for which the substrate transferring part the substrate from the sealed container or introduces the substrate into the sealed container, according to a substrate processing time period in the processing part.

Further, in a seventh aspect, there is provided a substrate processing method for performing processing on a substrate in a substrate processing apparatus including an opening/closing part adapted to open and close an opening formed in a sealed container for enabling introducing or discharging the substrate therein and therefrom, a substrate transferring part adapted to introduce or discharge the substrate through the opening, and a processing part adapted to perform predetermined processing on the substrate, wherein the substrate processing method includes (a) a step of creating a processing schedule for performing processing on the substrate in the processing part, and (b) a step of determining a timing at which the opening/closing part opens and closes the opening in the sealed container, based on the schedule.

Further, in an eighth aspect, in the substrate processing method in the seventh aspect, the step (b) is a step of determining the timing, such that the opening/closing part closes the opening portion, when a time width until the substrate transferring part next starts discharging a substrate from the sealed container or starts introducing a substrate into the sealed container is longer than a time width which is a sum of a time width required for a closing operation of the opening/closing part and a time width required for an opening operation of the opening/closing part, in a state where the opening has been opened by the opening/closing part.

Further, in a ninth aspect, in the substrate processing method in the seventh or eighth aspect, the step (b) is a step of determining the timing, such that the opening/closing part starts opening the opening, at an earlier timing, by equal to or more than a time width required for an opening operation of the opening/closing part, than a time at which the substrate transferring part is to next start discharging a substrate from the sealed container or to next start introducing a substrate into the sealed container, in a state where the opening has been closed by the opening/closing part.

Further, in a tenth aspect, in the substrate processing method in any one of the seventh to ninth aspects, the substrate processing apparatus includes an inert-gas supply part for supplying an inert gas to an inside of the container, and a concentration acquisition part for acquiring an inert-gas concentration within the sealed container, and the step (b) is a step of determining the timing, such that the opening/closing part closes the opening, when the inert gas concentration acquired by the concentration acquisition part is lower than a predetermined reference value.

Further, in an eleventh aspect, in the substrate processing method in any one of the seventh to tenth aspects, the opening/closing part includes a first opening/closing part for closing the opening, and a second opening/closing part for closing the opening, such that, when the opening is closed thereby, the sealed container is sealed to a lower degree than when the opening is closed by the first opening/closing part, and the step (b) is a step of determining a timing of an opening/closing operation of the second opening/closing part.

### Effects of the Invention

With the substrate processing apparatus in the first aspect, it is possible to preliminarily determine the time periods for which the opening in the sealed container is opened and closed, through the schedule. This enables preventing the sealed container from being wastefully opened, according to the types of substrates, thereby alleviating damages exerted on the substrates. Further, this enables opening the sealed container beforehand, in such a way as to coincide with the time periods for which the substrate is discharged from the sealed container or the substrate is introduced into the sealed container, which can suppress the reduction of the operating ratio of the substrate.

With the substrate processing apparatus in the second aspect, it is possible to open and close the opening in the sealed container, in such a way as not to obstruct the discharging or introducing of the substrate by the substrate transferring part. This can alleviate damages exerted on the substrates within the sealed container.

With the substrate processing apparatus in the third aspect, it is possible to certainly open the opening beforehand, before the substrate transferring part intrudes into the sealed container for taking out the substrate therefrom. This enables smoothly taking out the substrate therefrom. This enables performing the substrate processing with higher efficiency.

With the substrate processing apparatus in the fourth aspect, it is possible to maintain the inert-gas concentration within the sealed container at the reference value or more. This can alleviate damages exerted on the substrates within the sealed container.

With the substrate processing apparatus in the fifth aspect, it is possible to open and close the opening in the sealed container through the second opening/closing part while keeping the first opening/closing part opened, which enables easily opening and closing the opening. This can shorten the time width required for the opening operation or the time width required for the closing operation, thereby increasing the degree of freedom in creating the schedule.

### BRIEF DESCRIPTION OF DRAWINGS

FIG. 1 is a schematic plan view of a substrate processing apparatus according to an embodiment.

FIG. 2 is a schematic side view of the substrate processing apparatus.

FIG. 3 is a schematic cross-sectional view illustrating a sealed container placed on a container placement portion.

FIG. 4 is a block diagram illustrating the hardware structure of a control part.

FIG. 5 is a block diagram illustrating the structure of the substrate processing apparatus.

FIG. 6 is a flow diagram illustrating an example of operations of the substrate processing apparatus.

FIG. 7 is a time chart illustrating the flow of operations of the substrate processing apparatus which is defined by a temporary time table.

FIG. 8 is a time chart illustrating an example of a schedule which defines substrate processing operations.

FIG. 9 is a time chart illustrating an example of a schedule which defines time periods of opening/closing operations.

FIG. 10 is a time chart illustrating an example of another schedule which defines time periods of opening/closing operations.

### DESCRIPTION OF EMBODIMENTS

Hereinafter, embodiments of the present invention will be described, with reference to the accompanying drawings. Further, the following embodiments are examples of details of the present invention and are not instances which restrict the technical scope of the present invention. Further, in the drawings, for ease of understanding, respective portions may be illustrated in such a way as to exaggerate or simplify their sizes and their numbers, in some cases.

### 1. Embodiments

### 1.1. The structure and Functions of a Substrate Processing Apparatus

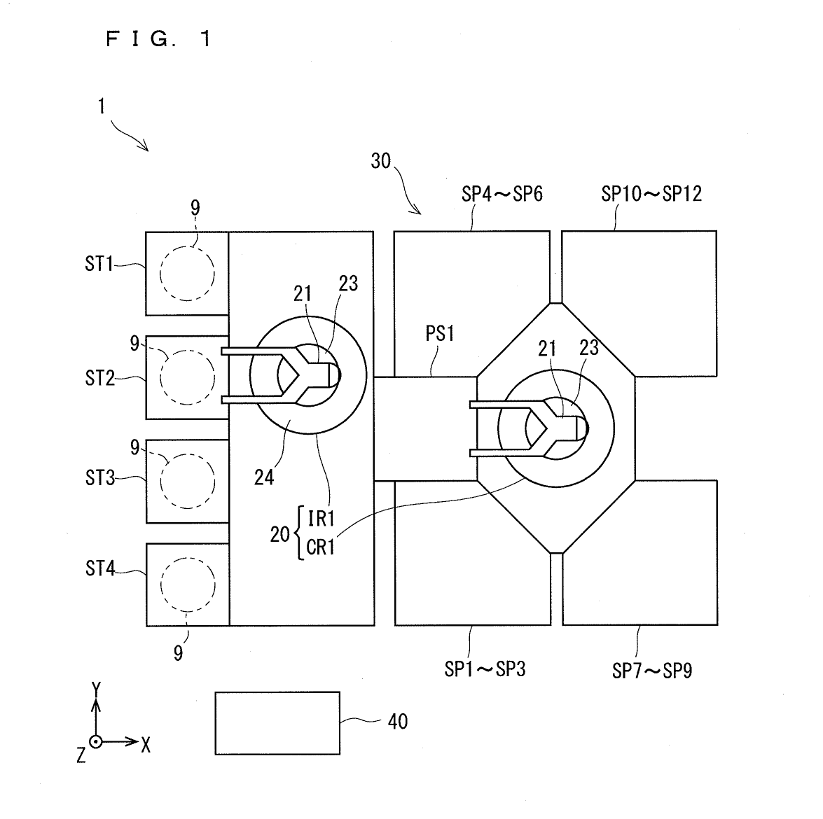

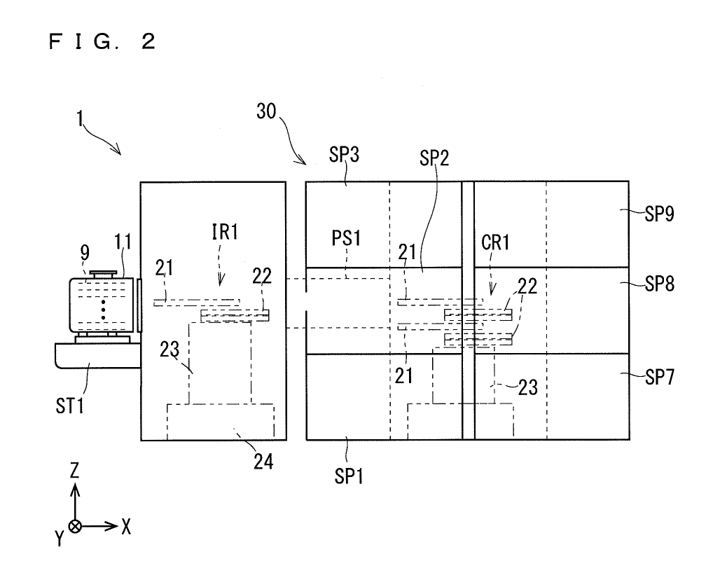

FIG. 1 is a schematic plan view of a substrate processing apparatus 1 according to an embodiment. Further, FIG. 2 is a schematic side view of the substrate processing apparatus 1. FIG. 1 and the respective figures thereafter are associated with an XYZ orthogonal coordinate system, in some cases, in order to clarify the positional relationship among respective components. In this XYZ orthogonal coordinate system, the X axis and the Y axis are assumed to define a plane which is a horizontal plane, while the Z axis is assumed to be in the vertical direction, for giving descriptions.

As illustrated in FIGS. 1 and 2, the substrate processing apparatus 1 includes four container placement portions ST1 to ST4, a substrate receiving/delivering portion PS1, a substrate transferring part 20 which includes a first transfer robot IR1 and a second transfer robot CR1, a substrate processing part 30 which includes plural cleaning units SP (SP1 to SP12), and a control part 40.

The substrate processing apparatus 1 is structured to be a cleaning process device for performing cleaning process on substrates 9 which are circular semiconductor wafers. However, the substrates 9 are not limited to those having circular shapes and can be also those having arbitrary shapes.

The container placement portions ST1 to ST4 form load ports for placing, thereon, sealed containers 11 which interiorly house plural substrates 9. These load ports can either be provided integrally with the main body portion (the portion provided with the substrate processing part 30 and the like) of the substrate processing apparatus 1 or be adapted to be mountable and detachable thereto and therefrom. The sealed containers 11 are introduced onto any of the container placement portions ST1 to ST4 or are discharged from any of the container placement portions ST1 to ST4, through a device outside the substrate processing apparatus 1 (for example, an overhead hoist transfer (OHT)).

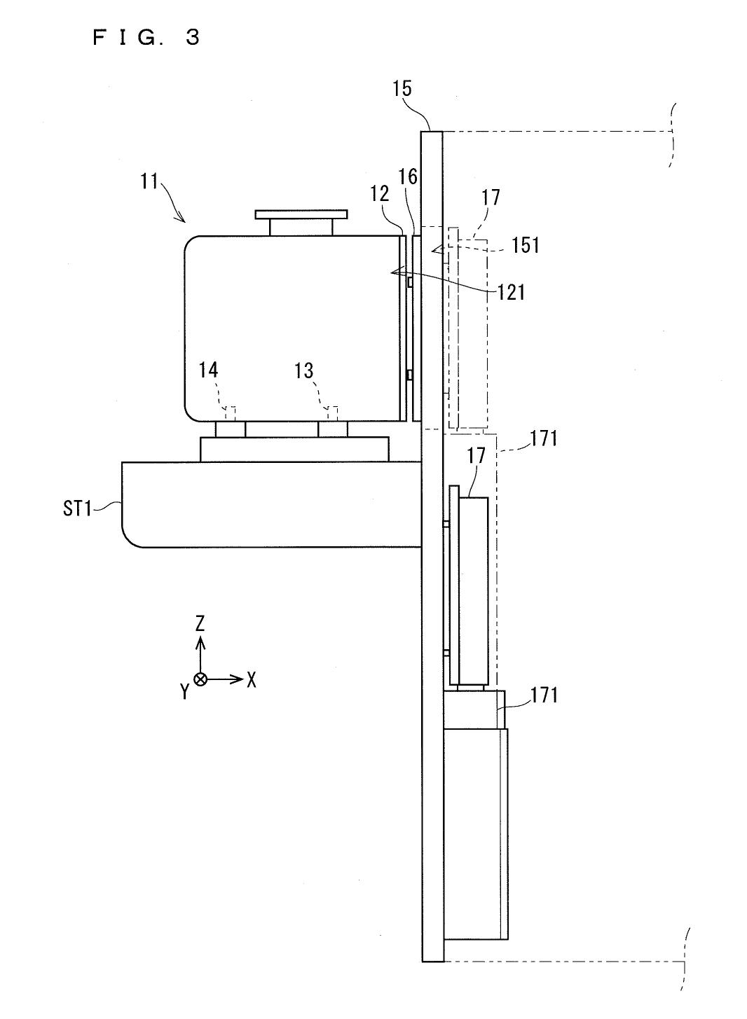

FIG. 3 is a schematic cross-sectional view illustrating a sealed container 11 placed on the container placement portion ST1. In this case, the container placement portion ST1 will be mainly described, but the container placement portions ST2 to ST4 also have substantially the same structure as that of the container placement portion ST1. As illustrated in FIG. 3, the sealed container 11 is provided with a lid part 12 in its side closer to the main body portion of the substrate processing apparatus 1 (in the +X-side). In a state where the lid part 12 is closed, the sealed container 11 is in a substantially-sealed state.

The sealed container 11 is structured such that its bottom portion can be connected to an inert-gas supply part 13 and a gas suction part 14 which are provided in the container placement portion ST1. If the sealed container 11 is placed on the container placement portion ST1, an inert gas (for example, N2, Ar, He, Kr or Xe gas, or a gas formed from a mixture of them) is supplied to the space inside the sealed container 11 (the substrate housing space) from the inert-gas supply part 13 connected to the bottom portion of the sealed container 11. Through this inert-gas supply part 13, it is possible to maintain the inert-gas concentration within the sealed container 11 at a higher concentration. Further, the ambient air within the sealed container 11 is discharged to the outside through the gas suction part 14.

As illustrated in FIG. 3, the container placement portion ST1 includes a frame 15 extending in the vertical direction. In the frame 15, there is formed a frame opening part 151 penetrated therethrough in the X-axis direction, at substantially the same height as that of the lid part 12 in the sealed container 11. Further, the frame 15 is provided with a lid opening/closing part 16 for detaching this lid part 12 from the sealed container 11 while holding it, in the vicinity of the +X-side surface of the lid part 12. The lid opening/closing part 16 is adapted such that it can be ascended and descended in the vertical direction, through an ascending/descending mechanism which is not illustrated. Further, the frame 15 is provided, in its +X side, with an opening/closing mechanism 17 for opening and closing the frame opening part 151. The opening/closing mechanism 17 is adapted such that it can be ascended and descended in the vertical direction, through an ascending/descending mechanism 171.

In a state where the lid part 12 has been detached from the sealed container 11 through the lid opening/closing part 16, if the opening/closing mechanism 17 is descended to open the frame opening part 151, this enables the first transfer robot IR1 to enter the inside of the sealed container 11 through an opening 121. Namely, the opening 121 in the sealed container 11 is brought into an opened state through the opening/closing mechanism 17, so that the first transfer robot IR1 is enabled to discharge the substrates 9 from the sealed container 11 or to introduce the substrates 9 into the sealed container 11.

Further, as indicated by two-dot chain lines in FIG. 3, the opening/closing mechanism 17 can be ascended to close the frame opening part 151. This causes the opening 121 in the sealed container 11 to be closed by the opening/closing mechanism 17, thereby realizing a state where the first transfer robot IR1 cannot enter the opening in the sealed container 11. However, in the state where the opening/closing mechanism 17 is closing the opening 121, there is formed a small gap between the sealed container 11 and the opening/closing mechanism 17. Therefore, the sealed container 11 is in a state of not being completely sealed. Thus, with the opening/closing mechanism 17, it is possible to close the opening 121 in a shorter time period, even with a lower degree of sealing, than in cases where the opening 121 is closed by the lid part 12 through the lid opening/closing part 16. In the present embodiment, the lid part 12 and the lid opening/closing part 16 are an example of a first opening/closing part, and the opening/closing mechanism 17 is an example of a second opening/closing part.

As illustrated in FIG. 1 or FIG. 2, the substrate transferring part 20 includes the first transfer robot IR1 and the second transfer robot CR1. The first transfer robot IR1 discharges the substrates 9 housed in the sealed containers 11 placed on the container placement portions ST1 to ST4 and places the substrates on the substrate receiving/delivering portion PS1. Further, the first transfer robot IR1 introduces, again, the substrates 9 placed on the substrate receiving/delivering portion PS1, into the sealed containers 11, after the substrate processing part 30 has performed predetermined substrate treatment (cleaning process, in this case). The first transfer robot IR1 includes a hand part 21 for supporting a substrate 9 at its lower side, an arm part 22 for moving the hand part 21 forward and rearward in the X-axis direction, and an ascending/descending mechanism 23 for ascending and descending the hand part 21 and the arm part 22 integrally in the Z-axis direction. Further, the first transfer robot IR1 includes a movement mechanism 24 which enables the entire first transfer robot IR1 to move in the Y-axis direction. By driving the movement mechanism 24, the first transfer robot IR1 is moved to positions corresponding to the respective container placement portions ST1 to ST4 and discharges or introduces the substrates 9.

The first transfer robot IR1 holds a substrate 9 with the hand part 21, at a horizontal attitude (in a state where the substrate 9 is parallel with the horizontal plane (the XY plane)). When the first transfer robot IR1 discharges a substrate 9 from a sealed container 11, the height of the hand part 21 is adjusted by the ascending/descending mechanism 23, depending on the height of the substrate 9 to be taken out, out of the plural substrates 9 housed in plural stages in the Z-axis direction. Further, when the first transfer robot IR1 introduces a substrate 9 into a sealed container 11, the height of the hand part 21 is adjusted by the ascending/descending mechanism 23, depending on the height at which the substrate 9 is to be housed.

The second transfer robot CR1 transfers the substrates 9 between the substrate receiving/delivering portion PS1 and any of the cleaning units SP 1 to SP 12. The second transfer robot CR1 includes two sets of hand part 21 and arm part 22 at upper and lower portions. These two sets of the hand parts 21 and the arm parts 22 can be adapted to be integrally ascended and descended upwardly and downwardly through the driving of the ascending/descending mechanism 23, but the respective sets can be also adapted to be ascended and descended individually. Further, the second transfer robot CR1 does not include the movement mechanism 24 and, therefore, is placed at a fixed position within the XY plane. However, the movement mechanism 24 can be also provided, in order to enable the second transfer robot CR1 to move in the X-axis and Y-axis directions.

Further, the first transfer robot IR1 can be also provided with two or more sets of hand part 21 and arm part 22, such that it is enabled to hold plural substrates 9 at the same time.

The substrate processing part 30 includes the plural cleaning units SP1 to SP12 which perform cleaning process on the substrates 9. As illustrated in FIG. 1, the second transfer robot CR1 is placed at a center portion of the substrate processing part 30. Further, around the second transfer robot CR1, the cleaning units SP1 to SP12 are installed, in such a way as to be divided into four groups (the cleaning units SP1 to SP3, the cleaning units SP4 to SP6, the cleaning units SP7 to SP9, and the cleaning units SP10 to SP12). The cleaning units SP1 to SP12 are stacked in the vertical direction, in the respective groups, to be placed in plural stages.

Although not illustrated, each of the cleaning units SP1 to SP12 includes a holding table for holding a substrate 9, a rotational mechanism for rotating this holding table, a nozzle for supplying a cleaning liquid (a chemical liquid or a rinse liquid) to the substrate 9 being held on the holding table, a collection mechanism for collecting the cleaning liquid, and the like. The cleaning units SP 1 to SP 12 rotate the substrate 9 for drying the substrate 9 (spin dry), after supplying the cleaning liquid to the substrate 9 according to recipe information.

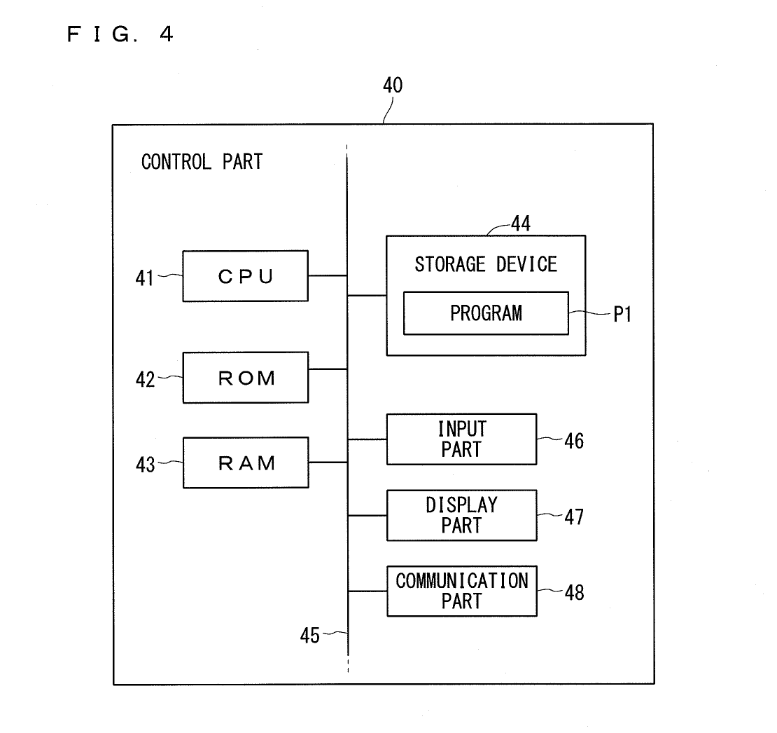

FIG. 4 is a block diagram illustrating the hardware structure of the control part 40. The control part 40 is electrically connected to respective portions included in the substrate processing apparatus 1 and controls operations of the respective portions in the substrate processing apparatus 1 while executing various types of arithmetic processes. As illustrated in FIG. 4, the control part 40 is constituted by, for example, an ordinary computer in which a CPU 41, a ROM 42, a RAM 43, a storage part 44 and the like are interconnected to each other through a bus line 45. The ROM 42 stores basic programs and the like. The RAM 43 is provided as a working area when the CPU 41 executes predetermined processes. The storage part 44 is constituted by a non-volatile auxiliary storage device such as a flash memory or a hard disk device.

The storage part 44 stores a program P1, and the CPU 41 as a main control part is adapted to execute arithmetic processes according to the procedure described in the program P1, thereby realizing various types of functions.

Generally, the program P1 is used by having been preliminarily stored in the storage part 44 and the like. However, the program P1 can either be provided in the form of a recording in a portable recording medium such as an optical medium (such as a CD-ROM), a magnetic medium, a semiconductor memory such as a flash memory, or be provided by being downloaded from an external server through a network, and be stored in the storage part 44 and the like.

Further, in the control part 40, an input part 46, a display part 47 and a communication part 48 are connected to the bus line 45. The input part 46 is constituted by various types of switches, a touch panel and the like and receives various types of input setting commands from an operator. The display part 47 is constituted by a liquid crystal display device, a lamp and the like and displays various types of information under the control of the CPU 41. The communication part 48 has the function of communicating data through a LAN and the like.

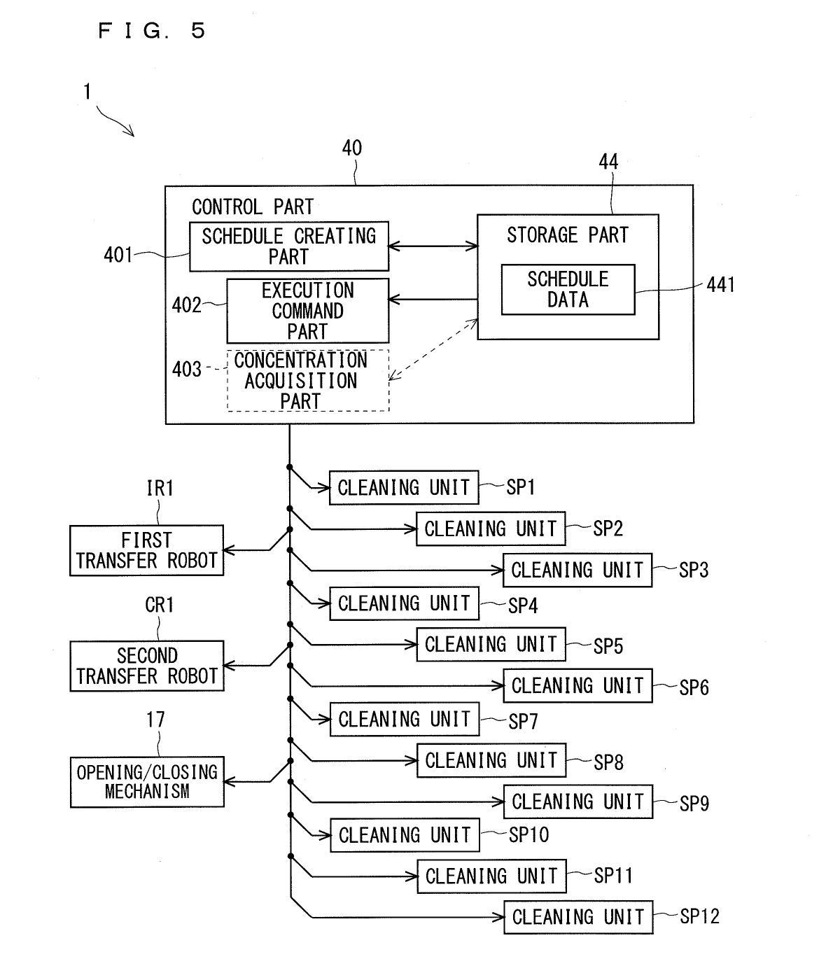

FIG. 5 is a block diagram illustrating the structure of the substrate processing apparatus 1. As illustrated in FIG. 5, in the control part 40, the CPU 41 as the main control part executes arithmetic processes according to the procedure described in the program P1, thereby realizing a schedule creating part 401 and an execution command part 402. Further, some or all of the functions realized by the control part 40 can be also realized in a hardware manner by dedicated logic circuits and the like.

The schedule creating part 401 creates a schedule which defines operations of the opening/closing mechanisms 17, the substrate transferring part 20 (the first transfer robot IR1 and the second transfer robot CR1), and the substrate processing part 30 (the cleaning units SP1 to SP12), based on recipe information which stores contents of processing. The recipe information describes, in a predetermined data form, conditions of the processing to be performed on the objects. More specifically, it describes processing procedures (for example, a transfer procedure and a cleaning process procedure) or the contents of processing (for example, processing time periods, temperatures, pressures or amounts of cleaning liquids to be supplied), and the like. This recipe information is created based on information inputted by the operator.

The schedule creating part 401 determines time periods for which the respective components in the substrate processing apparatus 1 operate (operation starting timings (clock times)), in such a way as to maintain a highest possible operating ratio of the substrate processing apparatus 1 (particularly, the cleaning units SP1 to SP12), based on the recipe information. More specifically, it defines time periods for which the opening/closing mechanisms 17 open and close the openings 121 in the sealed containers 11, time periods for which the first transfer robot IR1 transfers substrates 9, time periods for which the second transfer robot CR1 transfers the substrates 9, and time periods for which the respective cleaning units SP1 to SP12 perform cleaning process, and the like. Further, it can be considered that time periods for which other components operate (for example, time periods for which the lid opening/closing parts 16 open and close the openings 121) are defined. The schedule created by the schedule creating part 401 is stored as schedule data 441 in the storage part 44 (or the RAM 43).

Further, the time widths required for the operations of the respective components in the substrate processing apparatus 1 have been preliminarily determined on a component-by-component basis or are determined based on the recipe information. For example, the time widths required for the first transfer robot IR1 and the second transfer robot CR1 to transfer the substrates 9 have been preliminarily determined as time widths unique to these respective components. Further, the time widths required for the cleaning units SP1 to SP12 to clean the substrates 9 have been preliminarily determined according to the processing conditions defined by the recipe information. Accordingly, when the times at which the respective components starts operations have been determined, the times at which the respective components complete the operations can be automatically determined.

The execution command part 402 outputs control signals which command the execution of predetermined operations, to the respective components in the substrate processing apparatus 1, based on the schedule data 441 stored in the storage part 44 (or the RAM 43). More specifically, it commands the opening/closing mechanisms 17, the substrate transferring part 20 (the first transfer robot IR1, and the second transfer robot CR1), the cleaning units SP1 to SP12, and the like to execute operations.

### 1.2. Operations of the Substrate Processing Apparatus

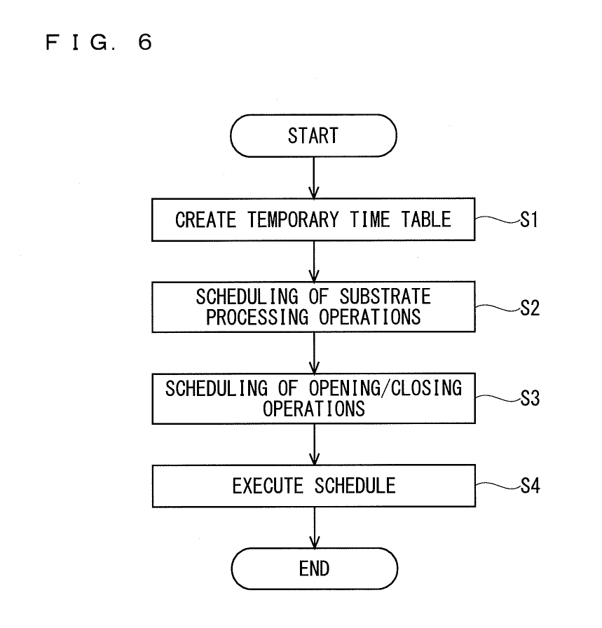

FIG. 6 is a flow diagram illustrating an example of operations of the substrate processing apparatus 1. At first, the schedule creating part 401 creates a temporary time table relating to the flow of a series of processing, for each of the substrates 9 to be subjected to the processing, based on the recipe information (step S1). The temporary time table defines a sequence of the processing to be performed on a single substrate 9 through the first transfer robot IR1, the second transfer robot CR1 and the cleaning units SPs.

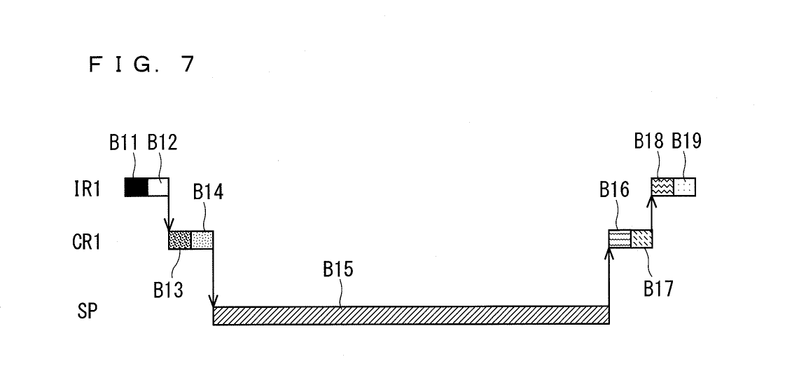

FIG. 7 is a time chart illustrating the flow of the operations of the substrate processing apparatus 1 which is defined by the temporary time table. As illustrated in FIG. 7, the temporary time table defines, at first, a time period for which the first transfer robot IR1 discharges a substrate 9 from a sealed container 11 (a discharge time period, a block B11), and a time period for which it introduces this substrate 9 into the substrate receiving/delivering portion PS1 (an introduction time period, a block B12). Further, the temporary time table defines a time period for which the second transfer robot CR1 discharges the substrate 9 having been placed on the substrate receiving/delivering portion PS1 by the first transfer robot IR1 (a discharge time period, a block B13), and a time period for which it introduces this substrate 9 into a cleaning unit SP in the substrate processing part 30 (an introduction time period, a block B14).

Further, the temporary time table defines a time period for which the cleaning unit SP performs cleaning process on the substrate 9 having been introduced by the second transfer robot CR1 (a substrate processing time period, a block B15). Further, the temporary time table defines a time period for which the second transfer robot CR1 discharges the substrate 9 having been subjected to the cleaning process (a discharge time period, a block B16), and a time period for which it introduces this substrate 9 into the substrate receiving/delivering portion PS1 (an introduction time period, a block B17). Further, the temporary time table defines a time period for which the first transfer robot IR1 discharges the substrate 9 having been placed on the substrate receiving/delivering portion PS1 by the second transfer robot CR1 (a discharge time period, a block B18), and a time period for which it introduces this substrate 9 into the sealed container 11 (an introduction time period, a block B19).

Next, the schedule creating part 401 performs scheduling for substrate processing operations (step S2). More specifically, the schedule creating part 401 determines the order of the treatment, according to predetermined rules, for the plural substrates 9 to be subjected to the treatment. Further, according to the determined order, the schedule creating part 401 combines, in order, the temporary time tables indicating the flows of the respective treatment for all the substrates 9. This results in creation of a schedule (treatment schedule) which defines the time periods for which the first transfer robot IR1, the second transfer robot CR1 and the cleaning units SP1 to SP12 perform respective operations.

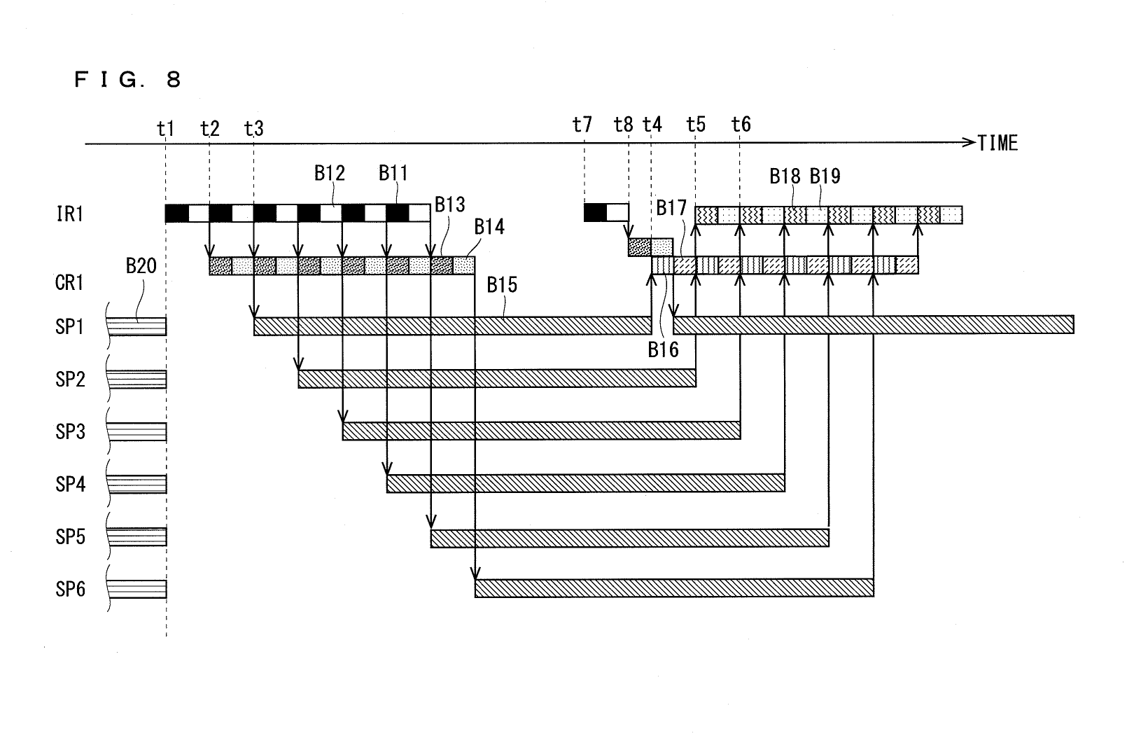

FIG. 8 is a time chart illustrating an example of a schedule which defines substrate processing operations. Further, the schedule illustrated in FIG. 8 is an example of a schedule for discharging and introducing substrates 9 only from the sealed container 11 placed on the container placement portion ST1 and, also, for performing cleaning process using only the six processing units SP which are the cleaning units SP1 to SP6, for ease of understanding. As illustrated in FIG. 8, the schedule created in Step S2 defines the time periods for which the first transfer robot IR1, the second transfer robot CR1 and the respective cleaning units SP1 to SP6 perform respective operations, along with the elapse of time.

More specifically, according to the schedule illustrated in FIG. 8, the first transfer robot IR1 discharges a first substrate 9 from the sealed container 11 and introduces it into the substrate receiving/delivering portion PS1, between a time t1 and a time t2. Further, the second transfer robot CR1 discharges the first substrate 9 from the substrate receiving/delivering portion PS1 and introduces it into the cleaning unit SP1, between the time t2 and a time t3.

Further, the cleaning unit SP1 cleans the first substrate 9 between the time t3 and a time t4. Further, the second transfer robot CR1 discharges the first substrate 9 from the cleaning unit SP1 and introduces it into the substrate receiving/delivering portion PS1, between the time t4 and a time t5. Further, the first transfer robot IR1 discharges the first substrate 9 from the substrate receiving/delivering portion PS1 and introduces it into the sealed container 11, between the time t5 and a time t6. As described above, the flow of the series of treatment for the first substrate 9 is defined in the schedule data 441.

Further, according to the schedule illustrated in FIG. 8, a transferring process is started, for a next or second substrate 9, at the time when the first transfer robot IR1 has completed the transfer of the previous or first substrate 9 (the time t2). Namely, the first transfer robot IR1 discharges the second substrate 9 from the sealed container 11 and introduces it into the substrate receiving/delivering portion PS 1, between the time t2 and the time t3. Thus, the first transfer robot IR1 executes the transfer of the next substrate 9 after the time point when it has completed the transfer of the previous substrate 9, so that it successively transfers the first to sixth substrates 9 from the sealed container 11 to the substrate receiving/delivering portion PS1.

Similarly, the second transfer robot CR1 executes the transfer of the next substrate 9 after the time point when it has completed the transfer of the previous substrate 9, so that it successively transfers the first to sixth substrates 9 from the substrate receiving/delivering portion PS1 to the respective cleaning units SP1 to SP6.

Further, after the cleaning unit SP 1 completes the cleaning process on the first substrate 9, the second transfer robot CR1 introduces a seventh substrate 9 into this cleaning unit SP 1. In order to catch up with the introduction of the seventh substrate by the second transfer robot CR1, the first transfer robot IR1 starts discharging the seventh substrate 9 from the sealed container 11 at a certain time point (a time t7) within the time period during which the cleaning unit SP1 performs the cleaning process (from the time t3 to the time t4), and it introduces it into the substrate receiving/delivering portion PS1. Further, the second transfer robot CR1 starts discharging the seventh substrate 9 from the substrate receiving/delivering portion PS1, at a time t8, in such a way as to catch up with the timing of the completion of the cleaning process on the first substrate by the cleaning unit SP1. Further, the second transfer robot CR1 introduces this substrate 9 into the cleaning unit SP1 by the time t4.

At this time point of the time t4, the first substrate 9 having been subjected to the cleaning process is left in the cleaning unit SP 1. Therefore, the second transfer robot CR1 takes out the first substrate 9, therefrom, with one of the hand parts 21, at first. Then, it introduces the seventh substrate 9 being held by the other hand part 21, into the cleaning unit SP1. Thus, the cleaning unit SP1 can immediately start the cleaning process on the seventh substrate 9, after having completed the cleaning process on the first substrate 9. This enables increasing the operating ratio of the cleaning unit SP 1.

Further, as illustrated in FIG. 8, the schedule can be created, such that preliminarily processes (for example, initialization of the nozzles, operations for checking the rotations of the holding tables, and the like) indicated by blocks B20 are executed, as operations of the cleaning units SP1 to SP12, before the start of the cleaning process for the substrates 9.

As described above, the schedule defining the time periods for which the first transfer robot IR1, the second transfer robot CR1 and the respective cleaning units SP1 to SP12 perform processes is created in the step S2.

Returning to FIG. 6, the schedule creating part 401 performs scheduling for operations for opening and closing the sealed containers 11, after the completion of the scheduling of the substrate processing operations in the step S2 (step S3). More specifically, in this step, the schedule creating part 401 determines the time periods for which the opening/closing mechanisms 17 open and close the openings 121 in the sealed containers 11, in such a way as to coincide with the time periods for which the first transfer robot IR1 transfers the substrates 9 to and from the sealed containers 11, which have been defined in the step S2. This results in creation of a schedule which defines the time periods for which the opening/closing mechanisms 17 perform opening/closing operations.

Further, the schedule creating part 401 stores schedule data 441 indicating the schedule in the storage part 44 (or the RAM 43), after having completing the scheduling of the opening/closing operations in the step S3. Based on this schedule, the execution command part 402 in the substrate processing apparatus 1 generates commands of operations to the respective components, thereby performing the substrate process (step S4).

Regarding the step S3, the time periods for which the opening/closing mechanism 17 performs operations for opening and closing the openings 121 are determined according to the following opening/closing conditions.

### A First Opening/Closing Condition

At first, the first opening/closing condition is that, when an opening 121 is closed, the opening/closing mechanism 17 should start opening the opening 121, at an earlier timing by equal to or more than the time width required for an opening operation by the opening/closing mechanism 17 than the time at which the first transfer robot IR1 is to start discharging a substrate 9 from the sealed container 11 or is to start introducing a substrate 9 into the sealed container 11.

### A Second Opening/Closing Condition

Further, the second opening/closing condition is that, when an opening 121 has been brought into an opened state by the opening/closing mechanism 17, if the time width from this time point until the start of the next discharge of a substrate 9 from the sealed container 11 or the start of the next introduction of a substrates 9 into the sealed container 11 by the first transfer robot IR1 is longer than the time width which is the sum of the closing-operation necessary time period and the opening-operation necessary time period of the opening/closing mechanism 17, the opening/closing mechanism 17 should close the opening 121.

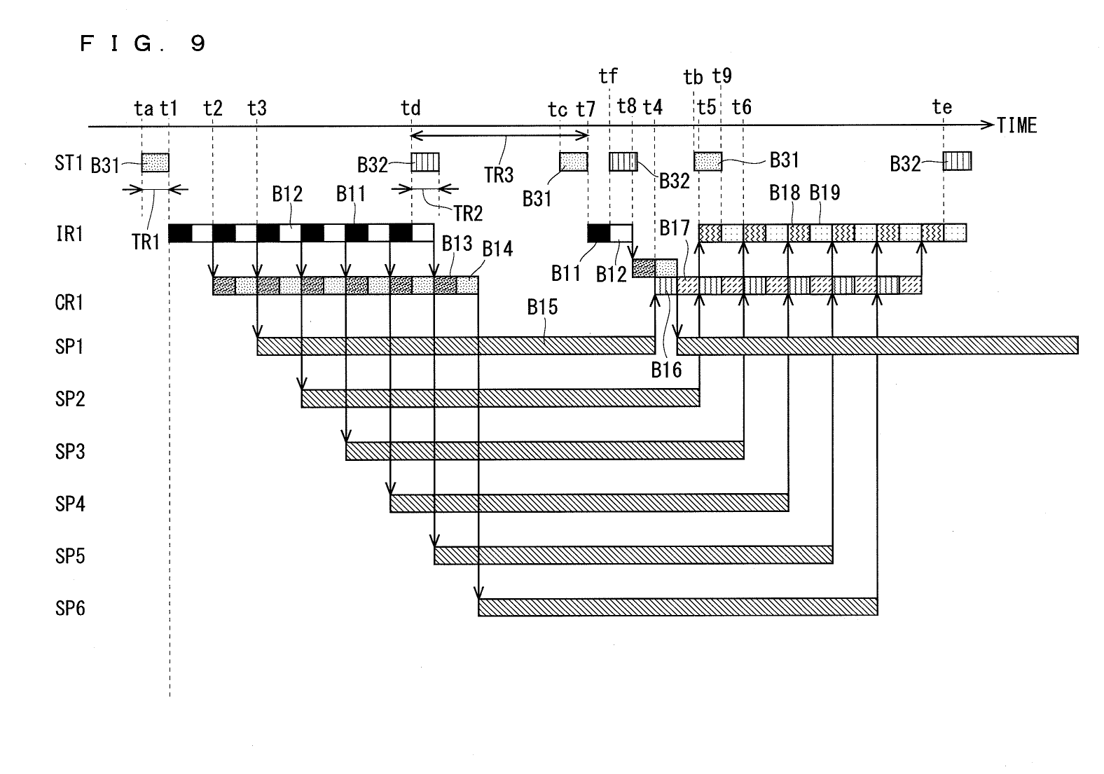

FIG. 9 is a time chart illustrating an example of a schedule which defines time periods of opening/closing operations. In FIG. 9, blocks B31 indicate time periods for which an opening/closing mechanism 17 opens a sealed container 11 (opening-operation time periods), and blocks B32 indicate time periods for which the opening/closing mechanism 17 closes the opening 121 in the sealed container 11 (closing-operation time periods).

Further, in the following description, it is assumed that the lid part 12 in the sealed container 11 is opened and closed beforehand by the lid opening/closing part 16. As a matter of course, the time periods for which the lid opening/closing part 16 performs these operations for opening and closing the lid part 12 can be also defined by the schedule creating part 401.

At first, there will be described a stage for determining the time periods of opening operations of the opening/closing mechanism 17, based on the first opening/closing condition. For example, according to the schedule illustrated in FIG. 9, the time at which the first transfer robot IR1 starts discharging the first substrate 9 from the sealed container 11 is t1. At this time point, the opening 121 is still in the state of being closed by the opening/closing mechanism 17. Therefore, the schedule is created such that the opening/closing mechanism 17 starts opening the opening 121, at an earlier timing (ta) than this time t1, by the time width required for an opening operation by the opening/closing mechanism 17 (an opening-operation necessary time period TR1), based on the first opening/closing condition.

Similarly, the schedule is created such that the opening/closing mechanism 17 starts opening the opening 121, at an earlier timing (tb) by the opening-operation necessary time period TR1 than the time (t9) at which the first transfer robot IR1 is to start introducing the first substrate 9 having been subjected to the cleaning process, into the sealed container 11.

Further, the opening/closing mechanism 17 starts opening the opening 121, at an earlier timing (tc) by the opening-operation necessary time period TR1 than the time (t7) at which the first transfer robot IR1 is to start discharging the seventh substrate 9 from the sealed container 11. Thus, the opening 121 has already been opened by the opening/closing mechanism 17, at the time points when the first transfer robot IR1 transfers the substrates 9 to and from the sealed container 11. This prevents the first transfer robot IR1 from being on standby until the opening 121 is opened. This can increase the operating ratio of the substrate processing apparatus 1.

As a matter of course, the times at which the opening/closing mechanism 17 starts opening the opening 121 can be made earlier than the aforementioned times t1, t9 and t7, by more than the opening-operation necessary time period TR1. However, in view of suppressing the opening of the opening 121 to a minimum necessary level for alleviating damages exerted on the substrates 9, it is preferable that the schedule is created such that the opening/closing mechanism 17 starts the opening operations, at earlier timings than the times t1, t9 and t7 by only the opening-operation necessary time period TR1, as described above.

Next, there will be described a stage for determining the time periods of closing operations of the opening/closing mechanism 17, based on the second opening/closing condition. For example, according to the schedule illustrated in FIG. 9, the time at which the first transfer robot IR1 completes the operation for discharging the sixth substrate 9 from the sealed container 11 is time td. At this time point, the opening 121 is being opened by the opening/closing mechanism 17, and the time at which the first transfer robot IR1 is to next start discharging a substrate 9 from the sealed container 11 or to next start introducing a substrate 9 into the sealed container 11 is the time t7. In this case, the time width TR3 from the time td to the time t7 is longer than the time width which is the sum of the opening-operation necessary time period TR1 and the closing-operation necessary time period TR2 of the opening/closing mechanism 17 for the opening 121 (TR3>TR1+TR2).

In this case, even if the opening 121 is closed at the time point of the time td, it is possible to secure a sufficient time period for opening it again, until the time t7 at which the first transfer robot IR1 is to next access the sealed container 11. Therefore, according to the second opening/closing condition, the opening/closing mechanism 17 is caused to close the opening 121 at the time point of the time td. Similarly, at the time point at which the sixth substrate 9 having been subjected to drying treatment has been introduced in the sealed container 11 (the time td), and at the time point at which the seventh substrate 9 has been discharged from the sealed container 11 (a time tf), the opening/closing mechanism 17 is caused to close the opening 121. This enables creating the schedule, such that the opening/closing mechanism 17 opens the opening 121 for only necessary time periods. This can inhibit the substrates within the sealed container 11 from suffering damages, such as oxidation, by being brought into contact with the external air.

Further, the schedule can be created, such that the opening/closing mechanism 17 starts closing operations, after the elapse of a predetermined time period (for example, several seconds to several tens of seconds) since the times td and tf.

Further, as other opening/closing conditions, it is also possible to determine the time periods for which the opening/closing mechanism 17 opens and closes the opening 121, based on the inert-gas concentration within the sealed container 11. For example, it is possible to determine the time periods for which the opening 121 can be opened, such that the inert-gas concentration within the sealed container 11 is maintained at a certain reference value. In this case, it is also possible to provide a concentration acquisition part 403 for acquiring inert-gas concentration changes within the sealed container 11, when the opening/closing mechanism 17 has opened the opening 121, through predetermined arithmetic processes such as simulations (see FIG. 5). As a matter of course, in cases where the schedule creating part 401 creates schedules independently of the inert-gas concentration, it is possible to eliminate this concentration acquisition part 403.

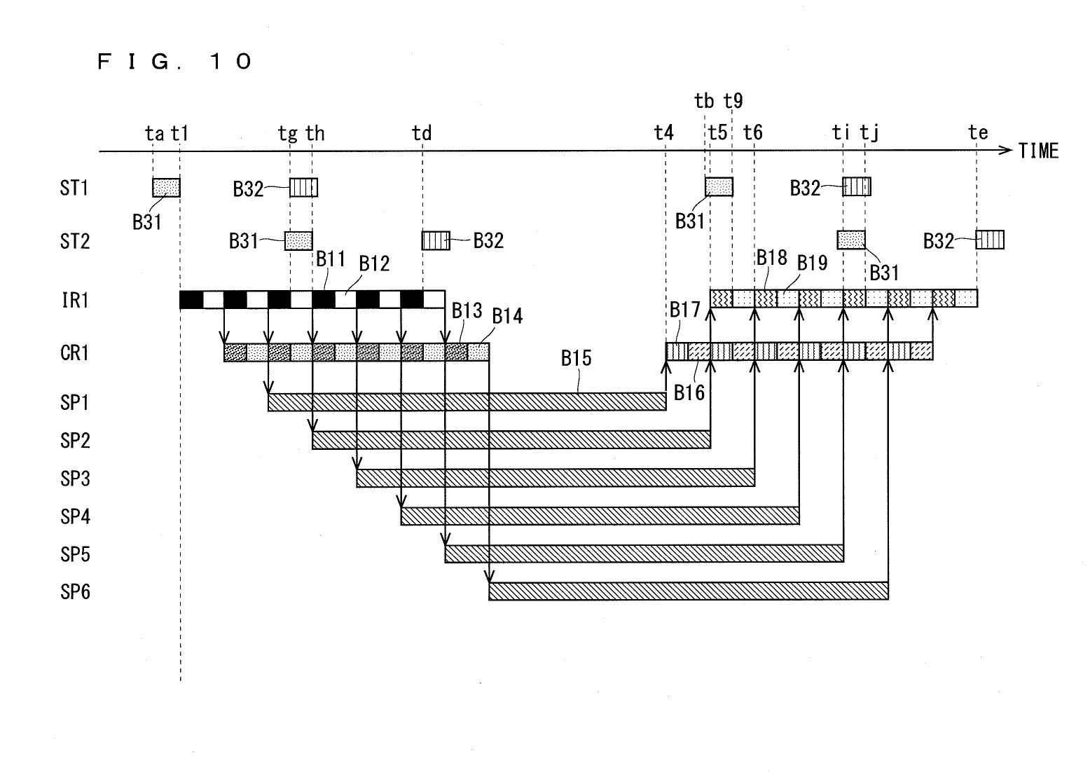

FIG. 10 is a time chart illustrating an example of another schedule which defines the time periods of opening/closing operations. In the example illustrated in FIG. 10, the schedule is created such that the first transfer robot IR1 discharges and introduces substrates 9, from and into the sealed containers 11 placed on the two container placement portions ST1 and ST2. More specifically, first to third substrates 9 are discharged from the sealed container 11 on the container placement portion ST1 or are introduced into the sealed container 11 on the container placement portion ST1. Further, fourth to sixth substrates 9 are discharged from the sealed container 11 on the container placement portion ST2 or are introduced into the sealed container 11 on the container placement portion ST2. Cleaning process is performed using only the cleaning units SP1 to SP6, which is similar to in the example illustrated in FIG. 8 and FIG. 9.

FIG. 10 illustrates schedule data 441 which is created by scheduling the operations of the first transfer robot IR1, the second transfer robot CR1 and the cleaning units SP1 to SP6 (FIG. 6: the step S2) and by, next, scheduling the opening/closing operations of the opening/closing mechanisms 17, according to the aforementioned first and second opening/closing conditions (FIG. 6: the step S3), similarly to the schedule data 441 illustrated in FIG. 9.

According to the schedule illustrated in FIG. 10, for example, before the time (t1) at which the first transfer robot IR1 starts discharging the first substrate 9 from the sealed container 11 on the container placement portion ST1, the opening 121 in the sealed container 11 is opened by the opening/closing mechanism 17 in the container placement portion ST1. Further, at the time point when the discharging of the third substrate 9 from the sealed container 11 has been completed (a time tg), the opening 121 in the sealed container 11 is closed by the opening/closing mechanism 17 in the container placement portion ST1.

Further, before the time (t9) at which the first transfer robot IR1 starts introducing the first substrate 9 having been subjected to the cleaning process into the sealed container 11 on the container placement portion ST1, the opening 121 in the sealed container 11 is opened by the opening/closing mechanism 17 in the container placement portion ST1. Further, at the time point when the first transfer robot IR1 has completed the introducing of the third substrate 9 having been subjected to the drying process into the sealed container 11 (a time ti), the opening 121 in the sealed container 11 is closed by the opening/closing mechanism 17 in the container placement portion ST1.

On the other hand, according to the schedule illustrated in FIG. 10, before the time (th) at which the first transfer robot IR1 starts discharging the fourth substrate 9 from the sealed container 11 on the container placement portion ST2, the opening 121 in the sealed container 11 is opened by the opening/closing mechanism 17 in the container placement portion ST2. Further, at the time point when the discharging of the sixth substrate 9 from the sealed container 11 has been completed (the time td), the opening 121 in the sealed container 11 is closed by the opening/closing mechanism 17 in the container placement portion ST2.

Further, before the time (ti) at which the first transfer robot IR1 starts introducing the fourth substrate 9 having been subjected to the cleaning process into the sealed container 11 on the container placement portion ST2, the opening 121 in the sealed container 11 is opened by the opening/closing mechanism 17 in the container placement portion ST2. Further, at the time point (a time te) when the first transfer robot IR1 has completed the introducing of the sixth substrate 9 having been subjected to the drying process into the sealed container 11, the opening 121 in the sealed container 11 is closed by the opening/closing mechanism 17 in the container placement portion ST2.

As described above, even when scheduling is performed for the opening/closing operations of the opening/closing mechanisms 17 for the sealed containers 11 on the plural container placement portions ST1 and ST2, it is possible to alleviate damages exerted on the substrates 9, similarly to in cases of using the sealed container 11 on a single container placement portion ST1. Further, before the first transfer robot IR1 discharges a substrate 9 from the sealed containers 11 or introduces a substrate 9 into the containers 11, the openings 121 in the sealed containers 11 can be opened beforehand. This can realize smooth transfer of substrates. This can suppress the reduction of the operating ratio of the substrate processing apparatus 1.

### 2. Examples of Modifications

Although an embodiment has been described above, the present invention is not limited to those described above, and various modifications can be made thereto.

For example, in the aforementioned embodiment, the schedule creating part 401 is adapted to perform scheduling of opening/closing operations of the opening/closing mechanisms 17. However, it is also possible to perform scheduling of operations for opening and closing the openings 121 by the lid opening/closing parts 16, instead of the opening/closing mechanisms 17. In this case, although the opening/closing operations may take longer time periods (namely, the opening-operation necessary time period TR1 and the closing-operation necessary time period TR2 may be made longer), the sealed containers 11 are sealed to a higher degree, which can alleviate damages exerted on the substrates 9 housed in the sealed containers 11, due to oxidation and the like.

Further, the schedule creating part 401 can be adapted to create schedules, such that the openings 121 are closed by the lid opening/closing parts 16 or the opening/closing mechanisms 17, depending on the situations. For example, it can be contrived that the openings 121 are closed by the lid parts 12 and the lid opening/closing parts 16 when the first transfer robot IR1 accesses the sealed containers 11 at relatively longer time intervals (namely, with a lower access frequency) and that the openings 121 are closed by the opening/closing mechanisms 17 when it accesses them at relatively shorter time intervals (namely, with a higher access frequency).

Further, in closed states through the opening/closing mechanisms 17, the position of the openings 121 in the sealed containers 11 can be moved to a position which is further intruded into the frame opening parts 151, from the position illustrated in FIG. 3, so that they can get closer to the opening/closing mechanisms 17. This enables further increasing the degree of sealing of the sealed containers 11, when the openings 121 are closed by the opening/closing mechanisms 17.

Further, it can be contrived that, in cases where the openings 121 in the sealed containers 11 are opened and closed by the lid parts 12 and the lid opening/closing parts 16, the lid opening/closing parts 16 can be adapted to merely cause the lid parts 12 to touch the opening edges of the sealed containers 11 for bringing them into intimate contact with each other, so that the lid parts 12 are prevented from being completely secured (locked) to the sealed containers 11. In this case, it is also possible to provide substantially the same sealing effect as that of when the sealed containers 11 are sealed by the lid opening/closing parts 16. Furthermore, in opening and closing the sealed containers 11, it is possible to shorten the time periods required for locking the lid parts 12 and for releasing the locking.

Further, the substrate processing part 30 in the substrate processing apparatus 1 includes the plural cleaning units SP1 to SP12. However, the present invention is also effective in cases where the substrate processing part 30 is constituted by only a single cleaning unit.

Further, the processing units provided in the substrate processing part 30 are not limited to those for performing cleaning process on substrates. For example, the substrate processing part 30 can be also provided with process units for performing any of respective processes for light exposure, drying, plasma etching and the like. Also, it is effective that the substrate processing part 30 is provided with plural types of process units for performing different processes.

Further, the substrates 9 are not limited to semiconductor wafers and can be also other substrates (printed boards, color-filter substrates, flat-panel-display glass substrates to be provided in liquid crystal display devices and plasma display devices, optical disk substrates, solar cell panels). In this case, the substrate processing apparatus 1 can be modified, according to the types of substrates. Further, the substrate processing apparatus 1 is not limited to one for performing cleaning process, and it can be contrived that the substrate processing apparatus 1 is modified to be devices for performing light exposure processes, development processes, plasma etching processes, drying processes and other processes.

Further, the respective structures described in the aforementioned respective embodiments and the respective modification examples can be properly combined, provided that they are not inconsistent with each other.

### DESCRIPTION OF REFERENCE CHARACTERS

1 Substrate processing apparatus

11 Sealed container

12 Lid part

121 Opening

13 Inert-gas supply part

16 Lid opening/closing part

17 Opening/closing mechanism

171 Ascending/descending mechanism

20 Substrate transferring part

30 Substrate processing part

40 Control part

401 Schedule creating part

402 Execution command part

403 Concentration acquisition part

441 Schedule data

9 Substrate

CR1 Second transfer robot

IR1 First transfer robot

P1 Program

PS1 Substrate receiving/delivering portion

SP (SP1 to SP12) Cleaning unit

ST1 to ST4 Container placement portion

TR1 Opening-operation necessary time period

TR2 Closing-operation necessary time period

1. A substrate processing apparatus for performing process on a substrate, comprising:
a sealed container provided with an opening for introducing and discharging a substrate therein and therefrom;
an opening/closing part adapted to open and close said opening;
a processing part adapted to perform predetermined process on said substrate;
a substrate transferring part adapted to discharge out the substrate from said sealed container or to introduce the substrate into said sealed container;
a schedule creating part adapted to create a schedule which defines a time period for which said opening/closing part opens and closes said opening, and a time period for which said substrate transferring part discharges the substrate from said sealed container or introduces the substrate into said sealed container, according to a substrate processing time period in said treatment portion; and
an execution command part adapted to command said opening/closing part and said substrate transferring part to execute operations, based on said schedule.

2. The substrate processing apparatus according to claim 1, wherein
said schedule creating part is adapted to create said schedule such that said opening/closing part closes said opening, when a time width until said substrate transferring part next starts discharging a substrate from said sealed container or starts introducing a substrate into said sealed container is longer than a time width which is a sum of a time width required for a closing operation of said opening/closing part and a time width required for an opening operation of said opening/closing part, in a state where said opening has been opened by the opening/closing part.

3. The substrate processing apparatus according to claim 1, wherein
said schedule creating part is adapted to create said schedule such that said opening/closing part starts opening said opening, at an earlier timing, by equal to or more than a time width required for an opening operation of said opening/closing part, than a time at which said substrate transferring part is to next start discharging a substrate from said sealed container or to next start introducing a substrate into said sealed container, in a state where said opening has been closed by said opening/closing part.

4. The substrate processing apparatus according claim 1, further comprising
an inert-gas supply part for supplying an inert gas to an inside of said container, and
a concentration acquisition part for acquiring an inert-gas concentration within said sealed container,
wherein
said schedule creating part is adapted to create said schedule, such that said opening/closing part closes said opening, when said inert-gas concentration acquired by said concentration acquisition part is lower than a predetermined reference value.

5. The substrate processing apparatus according to claim 1, wherein
said opening/closing part includes
a first opening/closing part for closing said opening, and
a second opening/closing part for closing said opening, such that, when said opening is closed thereby, said sealed container is sealed to a lower degree than when said opening is closed by said first opening/closing part, and
said schedule creating part is adapted to create a schedule which defines a timing of an opening/closing operation of said second opening/closing part.

6. A program which can be read by a computer, said program being adapted to be executed by said computer, thereby causing said computer to function as a schedule creating part in a substrate processing apparatus including a sealed container provided with an opening for introducing and discharging a substrate therein and therefrom, an opening/closing part adapted to open and close said opening, a processing part adapted to perform predetermined process on said substrate, and a substrate transferring part adapted to discharge the substrate from said sealed container or to introduce the substrate into said sealed container,
wherein the schedule creating part is adapted to create a schedule which defines a timing at which said opening/closing part opens and closes said opening, and a time period for which said substrate transferring part discharges the substrate from said sealed container or introduces the substrate into said sealed container, according to a substrate processing time period in said processing part.

7. A substrate processing method for performing process on a substrate in a substrate processing apparatus including an opening/closing part adapted to open and close an opening formed in a sealed container for enabling introducing or discharging the substrate therein and therefrom, a substrate transferring part adapted to introduce or discharge the substrate through said opening, and a processing part adapted to perform predetermined process on the substrate, the substrate processing method comprising
(a) a step of creating a processing schedule for performing process on the substrate in said processing part, and
(b) a step of determining a timing at which said opening/closing part opens and closes said opening in said sealed container, based on said processing schedule.

8. The substrate processing method according to claim 7, wherein
said step (b) is a step of determining said timing, such that said opening/closing part closes said opening portion, when a time width until said substrate transferring part next starts discharging a substrate from said sealed container or starts introducing a substrate into said sealed container is longer than a time width which is a sum of a time width required for a closing operation of said opening/closing part and a time width required for an opening operation of said opening/closing part, in a state where said opening has been opened by said opening/closing part.

9. The substrate processing method according to claim 7, wherein
said step (b) is a step of determining said timing, such that said opening/closing part starts opening said opening, at an earlier timing, by equal to or more than a time width required for an opening operation of said opening/closing part, than a time at which said substrate transferring part is to next start discharging a substrate from said sealed container or to next start introducing a substrate into said sealed container, in a state where said opening has been closed by said opening/closing part.

10. The substrate processing method according to claim 7, wherein
said substrate processing apparatus includes
an inert-gas supply part for supplying an inert gas to an inside of said container, and
a concentration acquisition part for acquiring an inert-gas concentration within said sealed container, and
said step (b) is a step of determining said timing, such that said opening/closing part closes said opening, when said inert gas concentration acquired by said concentration acquisition part is lower than a predetermined reference value.

11. The substrate processing method according to claim 7, wherein
said opening/closing part includes
a first opening/closing part for closing said opening, and
a second opening/closing part for closing said opening, such that, when said opening is closed thereby, said sealed container is sealed to a lower degree than when said opening is closed by said first opening/closing part, and
said step (b) is a step of determining a timing of an opening/closing operation of said second opening/closing part.
